(19) United States
(12) Patent Application Publication
(10) Pub. No.: US 2020/0313942 A1
(43) Pub. Date: Oct. 1, 2020

(54) TRANSMITTER AND METHOD

(71) Applicant: NEC CORPORATION, Tokyo (JP)

(72) Inventor: Noriaki TAWA, Tokyo (JP)

(73) Assignee: NEC CORPORATION, Tokyo (JP)

(21) Appl. No.: 16/827,070

(22) Filed: Mar. 23, 2020

(30) Foreign Application Priority Data
Mar. 28, 2019 (JP) 2019-064356

(51) Int. Cl. H04L 27/12; G06F 7/544; H03M 3/00

(52) U.S. Cl. CPC H04L 27/12; H03M 3/39; G06F 7/544

(57) ABSTRACT

A transmitter and a method capable of transmitting a transmission signal that satisfies a high S/N ratio are provided. A transmitter includes a first signal generation unit including a distributor configured to receive a first N (N: an integer greater than or equal to 3) value digital signal generated from a baseband signal, divide the first N-value digital signal into (N−1) binary digital signals, and output the divided (N−1) binary digital signals, and a signal amplification unit configured to amplify each of the (N−1) binary digital signals and output a transmission signal obtained by combining the amplified (N−1) signals.

### INCORPORATION BY REFERENCE

This application is based upon and claims the benefit of priority from Japanese patent application No. 2019-064356, filed on Mar. 28, 2019, the disclosure of which is incorporated herein in its entirety by reference.

### TECHNICAL FIELD

The present disclosure relates to a transmitter and a method.

### BACKGROUND ART

Commonly, signals can be amplified with high power efficiency by the use of a digital amplifier. A signal amplified by a digital amplifier is a pulse-modulated binary 1-bit digital signal with ON and OFF values.

Amplitude-phase-modulated signals are commonly used in mobile communication. In order to amplify such an amplitude-phase-modulated signal with a digital amplifier, it is necessary to convert the amplitude-phase-modulated signal into a pulse-modulated signal. The ΔΣ modulation (delta-sigma modulation) is often used when an amplitude-phase-modulated signal is converted into a pulse-modulated signal, (e.g., International Patent Publication No. WO 2017/037880). International Patent Publication No. WO 2017/037880 discloses a transmitter using a binary ΔΣ modulator.

In the ΔΣ modulation, quantization noise generated when an analog signal is converted into a digital signal is shaped, and the quantization noise moves to a high frequency side, so that pulse modulated signal with a high S/N ratio (SNR: Signal-to-Noise Ratio) can be obtained.

In mobile communication and the like, a high S/N ratio is required. Thus, even when binary ΔΣ modulation is used, an oversampling rate several tens of times more than usual is required to satisfy the required S/N ratio, and thus the sampling rate tends to increase. Thus, it is difficult to achieve a transmitter that transmits a transmission signal satisfying a high S/N ratio, because the signal processing speed is increased, and the cost and power consumption are also increased.

### SUMMARY

The present disclosure has been made to solve the above-described problem. An object of the present disclosure is to provide a transmitter and a method capable of transmitting a transmission signal that satisfies a high S/N ratio.

In order to solve the above problem, a transmitter according to the present disclosure includes:

a first signal generation unit comprising a distributor configured to input a first N (N: an integer greater than or equal to 3) value digital signal generated from a baseband signal, divide the first N-value digital signal into (N−1) binary digital signals, and output the (N−1) binary digital signals; and a signal amplification unit configured to amplify each of the (N−1) binary digital signals and output a transmission signal obtained by combining the amplified (N−1) signals.

In order to solve the above problem, a method according to the present disclosure includes:

dividing a first N (N: an integer greater than or equal to 3) value digital signal generated from a baseband signal into (N−1) binary digital signals and outputting the (N−1) binary digital signals; and

amplifying each of the (N−1) binary digital signals and outputting a transmission signal obtained by combining the amplified (N−1) signals.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 shows a configuration example of a transmitter according to a first example embodiment;

FIG. 2 shows a configuration example of a transmitter according to a second example embodiment;

FIG. 3 shows a configuration example of the transmitter according to the second example embodiment;

FIG. 4 shows an example of a time chart of each signal in the transmitter according to the second example embodiment;

FIG. 5 is a flowchart showing an operation example of an N-value signal distributor according to the second example embodiment;

FIG. 6 shows a result of a comparison between a transmitter using a binary ΔΣ modulator and a transmitter using a ternary ΔΣ modulator; and

FIG. 7 shows an operation example of an N-value signal distributor according to a modified example of the second example embodiment.

### EMBODIMENTS

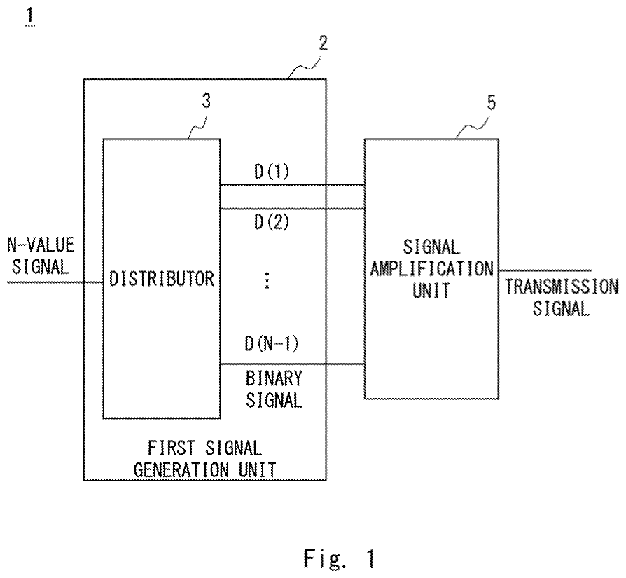

Hereinafter, example embodiments of the present disclosure will be described with reference to the drawings. Note that the following descriptions and drawings are omitted and simplified in order to clarify the descriptions. In the following drawings, the same elements are denoted by the same reference signs, and repeated descriptions are omitted as necessary. [First example embodiment] A transmitter 1 according to a first example embodiment will be described with reference to FIG. 1. FIG. 1 shows a configuration example of a transmitter according to the first example embodiment. The transmitter 1 may be a transmitter of a radio base station. The radio base station may be, for example, a relay node (RN) or an access point. Alternatively, the radio base station may be, for example, NR NodeB (NR NB), gNodeB (gNB), or eNodeB (evolved Node B). When the radio base station includes a CU (Central Unit) and a DU (Distributed Unit), the transmitter 1 may be a transmitter included in the DU.

The transmitter 1 includes a first signal generation unit 2 and a signal amplification unit 5.

The first signal generation unit 2 inputs a first N (N: integer greater than or equal to 3) value digital signal generated from a baseband signal, divides the received first N-value digital signal into (N−1) binary digital signals, and outputs the divided (N−1) binary digital signals.

The first signal generation unit 2 includes a distributor 3. The distributor 3 inputs the first N (N: integer greater than or equal to 3) value digital signal generated from a baseband signal, and divides the received first N-value digital signal into (N−1) binary digital signals, and outputs the divided (N−1) binary digital signals.

The signal amplification unit 5 amplifies each of the (N−1) binary digital signals output from the first signal generation unit 2 and combines the amplified (N−1) signals and outputs a transmission signal obtained by combining the amplified (N−1) signals.

With the above-described configuration of the transmitter 1, the transmitter 1 can output (transmit) a transmission signal with a high S/N ratio equivalent to that of a first N-value digital signal generated from a baseband signal. That is, by using the transmitter 1 according to the first example embodiment, it is possible to transmit a transmission signal that satisfies an S/N ratio higher than an S/N ratio achieved by a transmission signal transmitted from a transmitter according to related art using a binary ΔΣ modulator.

### Second Example Embodiment

Next, a second example embodiment will be described. The second example embodiment is a specific example embodiment of the first example embodiment.

### <Configuration Example of Transmitter>

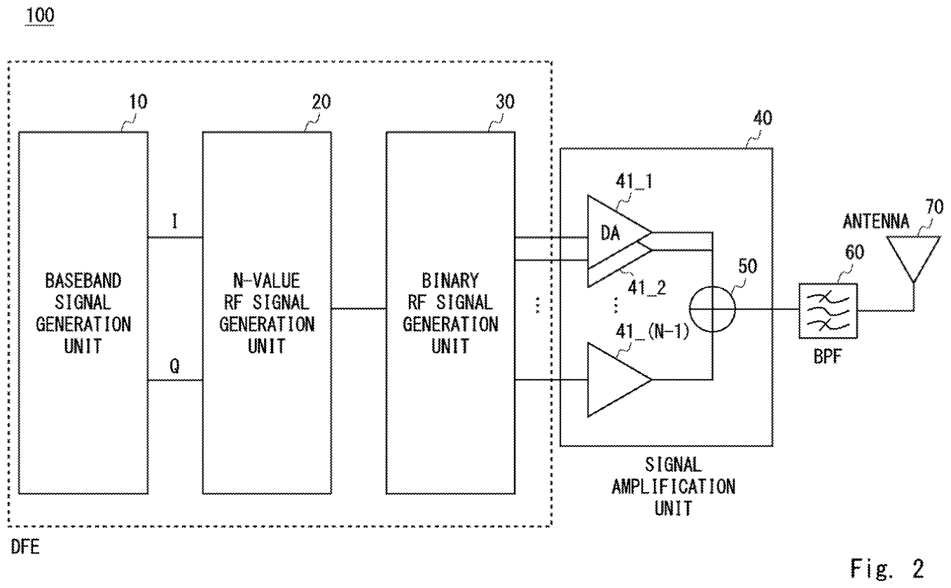

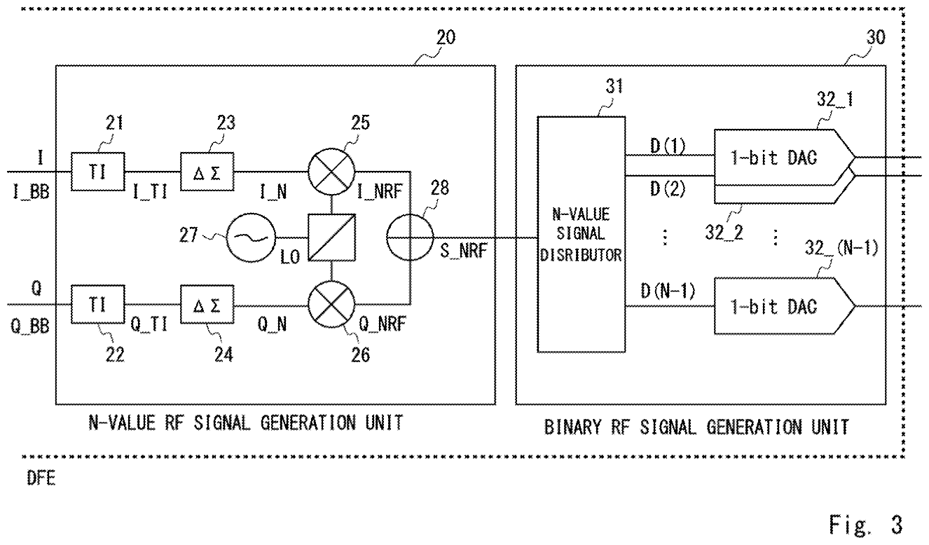

A transmitter 100 according to the second example embodiment will be described with reference to FIGS. 2 and 3. FIGS. 2 and 3 show a configuration example of a transmitter according to the second example embodiment.

The transmitter 100 is a transmitter used at, for example, an RF end of a radio base station. The radio base station is, for example, a radio base station in the fifth generation mobile communication system, and includes a CU and a DU. The transmitter 100 is a transmitter used inside the DU. A transmission signal transmitted from the radio base station is transmitted from the CU to the DU via an optical cable, converted into an RF signal by the DU, the converted RF signal is amplified, and then the amplified RF signal is transmitted from an antenna.

FIG. 2 schematically shows processing from generation of a baseband signal, conversion of the baseband signal into an RF signal having a carrier frequency Fc, and transmission of the RF signal from the antenna. The transmission signal transmitted from the transmitter 100 is, for example, an OFDM (Orthogonal Frequency Division Multiplexing) modulation signal.

As shown in FIG. 2, the transmitter 100 includes a baseband signal generation unit 10, an N-value RF signal generation unit 20, a binary RF signal generation unit 30, a signal amplification unit 40, and a Band-Pass Filter (BPF) 60, and an antenna 70.

The baseband signal generation unit 10, the N-value RF signal generation unit 20, and the binary RF signal generation unit 30 are referred to as a Digital Front End (DFE) and are configured by digital circuits. That is, the baseband signal generation unit 10 may be configured by a baseband signal generation circuit, the N-value RF signal generation unit 20 may be configured by an N-value RF signal generation circuit, and the binary RF signal generation unit 30 may be configured by a binary RF signal generation circuit. The DFE may be configured by a Field-Programmable Gate Array (FPGA), an Application Specific Integrated Circuit (ASIC), or the like.

The baseband signal generation unit 10 has the same configuration as that of the baseband signal generation unit of the transmitter according to the related art. The baseband signal generation unit 10 generates an amplitude-phase-modulated baseband signal based on information transmitted from a CU (not shown). The baseband signal generation unit 10 generates an amplitude-phase-modulated signal with a baseband bandwidth and outputs an in-phase channel signal (I channel signal) and a quadrature-phase channel signal (Q channel signal) orthogonal to the I channel signal. Each of the I channel signal and the Q channel signal is a multi-bit signal.

The baseband signal generation unit 10 changes the sampling rate so that the sampling rate of the baseband signal becomes 2Fc/K. Fc is a carrier frequency, and K is a coefficient used in time interleaving units 21 and 22 included in the N-value RF signal generation unit 20, which will be described later.

The N-value RF signal generation unit 20 performs time interleaving processing on the I channel signal and the Q channel signal output from the baseband signal generation unit 10, performs ΔΣ modulation on the N-value signal, up-converts a frequency to a carrier frequency Fc, and outputs the N-value RF signal which is an N-value digital signal. A specific configuration of the N-value RF signal generation unit 20 will be described later.

The binary RF signal generation unit 30 divides the N-value RF signal output from the N-value RF signal generation unit 20 into binary RF signals, which are (N−1) binary digital signals, and outputs them.

Here, the configurations of the N-value RF signal generator 20 and the binary RF signal generation unit 30 will be described with reference to FIG. 3.

The N-value RF signal generation unit 20 includes the time interleaving (TI) units 21 and 22, ΔΣ modulators 23 and 24, mixers 25 and 26, a local oscillator 27, and a synthesizer 28.

The time interleaving unit 21 performs time interleaving processing on the I channel signal output from the baseband signal generation unit 10 and outputs a signal repeated K times. That is, while sampling the I channel signal once, the time interleaving unit 21 repeatedly outputs the I channel signal K times. As described above, the sampling rate of the baseband signal is 2Fc/K. Thus, the sampling rate of the signal interleaved by the time interleaving unit 21 is K times higher than the sampling rate of the baseband signal and is 2Fc.

The time interleaving unit 22 performs time interleaving processing on the Q channel signal output from the baseband signal generation unit 10 and outputs a signal repeated K times. That is, while sampling the Q channel signal once, the time interleaving unit 22 repeatedly outputs the Q channel signal K times. The sampling rate of the signal interleaved by the time interleaving unit 22 is also K times higher than the sampling rate of the baseband signal and is 2Fc.

In the following descriptions, the I channel signal and the Q channel signal output from the baseband signal generation unit 10 are referred to as I_BB and Q_BB, respectively. Moreover, the time-interleaved signals output from the time interleaving units 21 and 22 are referred to as I_TI and Q_TI, respectively.

The ΔΣ modulator 23 is an N-value ΔΣ modulator, and ΔΣ-modulates the signal I_TI, and outputs a ΔΣ-modulated N-value digital signal (N-value ΔΣ signal). The ΔΣ modulator 24 is an N-value ΔΣ modulator, ΔΣ-modulates the signal Q_TI, and outputs a ΔΣ-modulated N-value digital signal (N-value ΔΣ signal). In the following descriptions, signals output from the ΔΣ modulators 23 and 24 are referred to as I_N and Q_N, respectively.

The Local Oscillator (LO) 27 outputs an LO signal (Local Oscillator signal).

The mixer 25 multiplies the N-value ΔΣ signal (signal I_N) output from the ΔΣ modulator 23 and the LO signal output from the local oscillator 27, and up-converts a frequency to the carrier frequency Fc. The mixer 26 multiplies the N-value ΔΣ signal (signal Q_N) output from the ΔΣ modulator 24 and the LO signal output from the local oscillator 27, and up-converts a frequency to the carrier frequency Fc.

The signal processing to up-convert the frequency to the carrier frequency Fc is calculated by a digital circuit. Commonly, a digital calculation of the up-converter needs a multi-bit signal. However, in this embodiment, it is possible to up-convert even a signal having a small N-value, because the sampling rate of the N-value ΔΣ signal in this embodiment is 2Fc.

In this embodiment, since the carrier frequency Fc is ½ of the sampling rate of the signal I_N and the signal Q_N, the value multiplied by the signal I_N and the signal Q_N is 1 or −1, thereby simplifying the calculation. In the following descriptions, the signals up-converted from the signal I_N and the signal Q_N are referred to as I_NRF and Q_NRF, respectively.

The synthesizer 28 combines the signal I_NRF and the signal Q_NRF and outputs one N-value RF signal. The synthesizer 28 combines the signals by alternately outputting the I-channel signal I_NRF and the Q-channel signal Q_NRF at a sampling rate twice as high as the sampling rate of the signals I_NRF and Q_NRF. Thus, the sampling rate of the signal output from the synthesizer 28 is 4Fc. In this manner, an N-value signal (N-value digital signal) up-converted to the RF band is generated and output from the synthesizer 28. In the following descriptions, the signal output from the synthesizer 28 is referred to as S_NRF.

The signal S_NRF is a signal having a maximum value of N−1 and a minimum value of −(N−1) and that can take every two values between the maximum value and the minimum value. That is, when N=3, the value of S_NRF is a signal that takes one of 2, 0, and −2. In this embodiment, it is described that the value that the signal S_NRF can take is every two values but may be, for example, every four values.

Next, the binary RF signal generation unit 30 will be described. The binary RF signal generation unit 30 corresponds to the first signal generation unit 2 according to the first example embodiment. The binary RF signal generation unit 30 includes an N-value signal distributor 31 and DAC (Digital to Analog Convertor) units 32_1 to 32_(N−1). Note that the DAC units 32_1 to 32_(N−1) may be collectively referred to as the DAC unit 32 when there is no need to distinguish between the respective DAC units 32_1 to 32_(N−1).

The N-value signal distributor 31 corresponds to the distributor 3 according to the first example embodiment. The N-value signal distributor 31 inputs the signal S_NRF that is an N-value digital signal output from the N-value RF signal generation unit 20 and divides the received signal S_NRF into binary RF signals D(n) (n=1, 2, . . . , N−1) which are (N−1) binary RF signals. The value that D(n) can take is High or Low. When High is 1, and Low is −1, the value that D(n) can take is 1 or −1.

The N-value signal distributor 31 divides the signal S_NRF in such a way that the number of times the values of the respective binary RF signals D(n) are changed becomes small. The number of times the value of the signal is changed means that, when the value of the binary RF signal D(n) is expressed by 1 and −1, the number of times the value of the signal changes, such as from 1 to −1 or −1 to 1. The N-value signal distributor 31 counts the number of times an output value of each of the (N−1) binary RF signals has changed. The N-value signal distributor 31 determines the output value of each of the (N−1) binary RF signals based on the counted number of times of the changes.

The N-value signal distributor 31 calculates a difference between an input value of the signal S_NRF that is an N-value digital signal to be input at the time t (t: integer greater than or equal to 1, and the unit of time t is a reciprocal of the sampling rate 4Fc) and an input value of the signal S_NRF to be input at the time t−1. The N-value signal distributor 31 changes the output values of the binary RF signals at the time t, where the number of the binary RF signals corresponds to the calculated difference, to a value different from the output value at the time t−1 in order from the smallest number of times of the changes. The number corresponding to the difference is a number obtained by dividing the calculated difference by a minimum change amount of the input value of the signal S_NRF. The number corresponding to the difference may be regarded as a number obtained by dividing the calculated difference by a discrete value interval, because the value that the input value of the signal S_NRF can take is an evenly spaced discrete value. In this embodiment, the minimum value of a change amount (minimum change amount) and the interval of the discrete value of the signal S_NRF is 2, and thus the number corresponding to the difference is obtained by dividing the calculated number by 2. That is, the N-value signal distributor 31 changes the output value of the binary RF signal at the time t to a value different from the output value at the time t−1 in an ascending order of the number of times of the changes. Here, the number of the binary RF signals that the output value is changed corresponds to a number obtained by dividing the above difference by 2. The binary RF signal D(n) whose output value is changed is particularly referred to as a binary RF signal D(n′).

The N-value signal distributor 31 uses the value determined based on the calculated difference as an output value of the binary RF signal D(n′) in which the output value at the time t is changed from the output value at time t−1. When the calculated difference is greater than 0, the N-value signal distributor 31 sets the output value of the binary RF signal D(n′) whose output value is changed to High. When the calculated difference is smaller than 0, the N-value signal distributor 31 sets the output value of the binary RF signal D(n′) whose output value is changed to Low. In the following descriptions, although it is described that High is 1 and Low is −1, values different from 1 and −1 may be used.

Each of the DAC units 32_1 to 32_(N−1) is a 1-bit DAC, receives the binary RF signal D(n) divided and output by the N-value signal distributor 31, and outputs it from the DFE.

Returning to FIG. 2, the signal amplification unit 40 will be described. The signal amplification unit 40 includes amplification units 41_1 to 41_(N−1) and a synthesizer 50. Note that, the amplification units 41_1 to 41_(N−1) may be referred to as the amplification unit 41 when the respective amplification units 41_1 to 41_(N−1) are not distinguished.

The amplification unit 41 is configured by a Digital Amplifier (DA). The amplification units 41_1 to 41_(N−1) receive D(1) to D(N−1), which are the binary digital signals output from the DAC units 32_1 to 32_(N−1), amplify the received binary digital signals, and then output the amplified binary digital signals to the synthesizer 50, respectively.

The synthesizer 50 receives the signals output from the amplification units 41_1 to 41_(N−1), combines the signals, and outputs the combined signal from the signal amplification unit 40. Then, a signal with the accuracy of the original N-value signal is obtained.

The BPF 60 receives the signal combined by the synthesizer 50, removes a signal out-of-band component, and outputs the signal with the signal out-of-band component removed. In this embodiment, since the N-value RF signal generation unit 20 includes the ΔΣ modulators 23 and 24, quantization noise shaped to outside the signal band is generated. The BPF 60 removes unnecessary components outside the signal band such as quantization noise generated in the ΔΣ modulators 23 and 24 and distortion components during signal amplification.

The antenna 70 radiates a transmission signal output through the BPF 60.

### <Operation Example of Transmitter>

Next, an operation example of the transmitter 100 according to a second example embodiment will be described with reference to FIGS. 2 and 3.

As shown in FIG. 2, the baseband signal generation unit 10 generates an amplitude-phase-modulated signal of a baseband band based on information transmitted from a CU (not shown), and outputs the I channel signal I_BB and the Q channel signal Q_BB to the N-value RF signal generation unit 20.

Next, as shown in FIG. 3, the time interleaving units 21 and 22 perform time interleaving of K times on the signal I_BB and the signal Q_BB, respectively. As described above, the sampling rates of the signal I_TI and the signal Q_TI that have been time interleaved by the time interleaving units 21 and 22 are 2Fc. Here, Fc is a carrier frequency.

The ΔΣmodulators 23 and 244ΔΣ modulate the signal I_TI and the signal Q_TI, and output signals I_N and Q_N, respectively, which are N-value signals.

The mixers 25 and 26 up-convert the signals I_N and Q_N to the carrier frequency Fc and output the up-converted signals I_NRF and Q_NRF, respectively.

The synthesizer 28 alternately outputs the signal I_NRF and the signal Q_NRF as the signal S_NRF at a sampling rate (4Fc) that is twice as high as that of the signals I_NRF and Q_NRF.

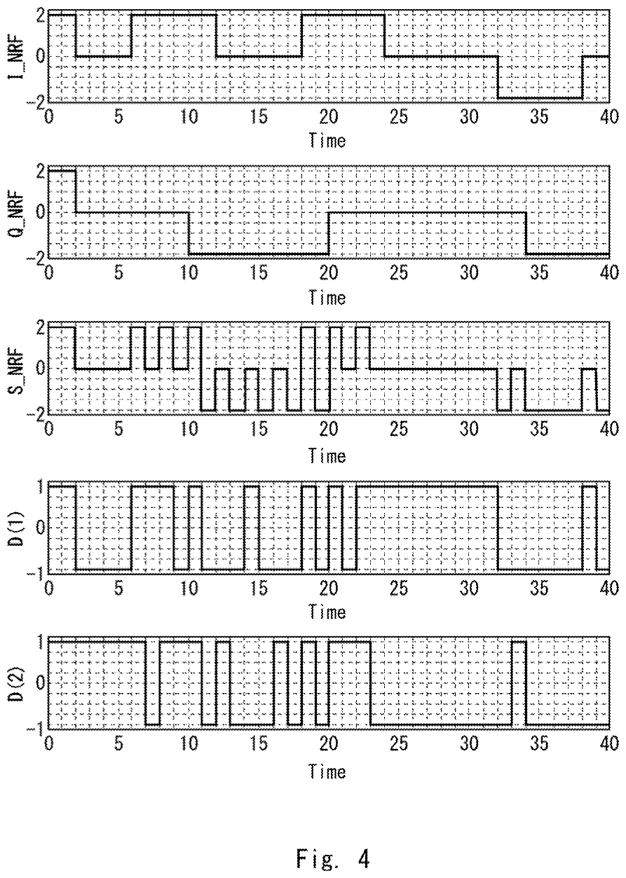

Here, a time chart of each signal when N=3 is shown using FIG. 4. FIG. 4 shows an example of a time chart of each signal in the transmitter according to the second example embodiment. In FIG. 4, the top diagram is a time chart of the signal I_NRF, and the second diagram from the top is a time chart of the signal Q_NRF. The third diagram from the top in FIG. 4 is a time chart of the signal S_NRF. The horizontal axis of each diagram in FIG. 4 represents time, and the vertical axis represents a value of each signal. The horizontal axes of the five diagrams shown in FIG. 4 correspond to each other and indicate the same time.

The signal I_NRF and the signal Q_NRF are an I channel signal and a Q channel signal that are up-converted to the RF band, respectively, and can take three values of 2, 0, and −2 when N=3. In FIG. 4, as an example, the two diagrams from the top are the time charts of the signal I_NRF and the signal Q_NRF. In these time charts, the synthesizer 28 outputs the signal I_NRF at the time 0, and the synthesizer 28 outputs the signal Q_NRF at the time 1.

As shown in FIG. 4, since the synthesizer 28 outputs the signal I_NRF at the time 0, the value of the signal I_NRF is output as the signal S_NRF. At the time 1, since the synthesizer 28 outputs the signal Q_NRF, the value of the signal Q_NRF is output as the signal S_NRF. After the time 2 onward, the synthesizer 28 alternately outputs the signal I_NRF and the signal Q_NRF as the signal S_NRF. Thus, the value of the signal S_NRF output from the synthesizer 28 will be as shown in the third time chart from the top in FIG. 4.

Returning to FIG. 3, the description will be continued.

The signal S_NRF output from the synthesizer 28 is input to the N-value signal distributor 31, and (N−1) binary signals D(n) are output. The value that D(n) can take is High (1) or Low (−1). The distribution processing in the N-value signal distributor 31 will be described later.

The binary RF signals D(n) divided and output by the N-value signal distributor 31 are output from the DFE by the respective DAC units 32.

Returning to FIG. 2, the description will be continued.

Each of the signals D(n) output from the DFE is amplified by the corresponding amplification unit 41, and the amplified signals are combined by the synthesizer 50. Then, the amplified signal satisfying the S/N ratio equivalent to the signal S_NRF is obtained. A single digital amplifier can only amplify binary signals. However, by using (N−1) digital amplifiers as in this embodiment, a signal with the accuracy equivalent to that of an N-value can be obtained.

The BPF 60 removes unnecessary components outside the band from the signal combined by the combiner 50, and then the antenna 70 transmits the combined signal with unnecessary components removed as a transmission signal.

### <Operation Example of N-Value Signal Distributor>

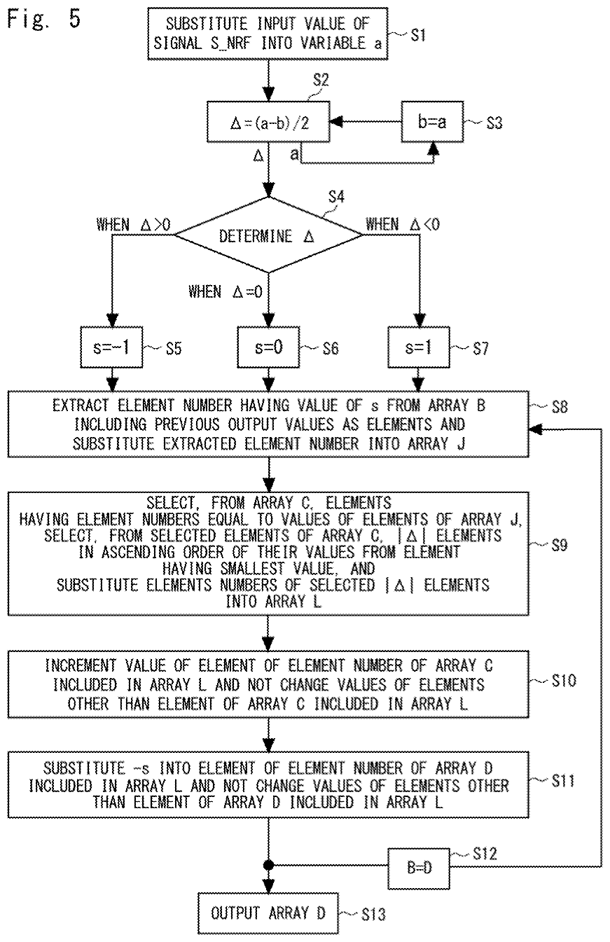

Next, an operation example of the N-value signal distributor 31 will be described with reference to FIG. 5. FIG. 5 is a flowchart of an operation example of the N-value signal distributor according to the second example embodiment. More specifically, FIG. 5 shows an example of a method for generating (N−1) binary RF signals D(n) from the signal S_NRF.

First, variables and arrays used in FIG. 5 will be described.

A variable into which the input value (value of signal S_NRF) of the N-value signal distributor 31 is substituted is a variable a, and a variable into which the previous input value (value of signal S_NRF one sample before) is substituted is a variable b. That is, the input value of the signal S_NRF at the time t (t: integer greater than or equal to 1) is substituted into the variable a, and the input value of the signal S_NRF at the time t−1 is held as the variable b. A value determined according to a difference between the variable a and the variable b is defined as a variable A.

An array D=[D(1), . . . , D(N−1)] including output values D(1), . . . , D(N−1) of the N-value signal distributor 31 as elements is defined. That is, the N-value signal distributor 31 uses the value of S_NRF as an input value and outputs the elements D(1), . . . , D(N−1) of the array D as an output value based on the array D. A variable s is defined as a variable used to determine the output value D(n). When the previous output values, which are B(1), . . . , B (N−1), are expressed by an array, they is defined as an array B=[B (1), . . . , B (N−1)].

The number of times each output value D(1), . . . , D(N−1) of the N-value signal distributor 31 is changed is defined as an array C. The nth value C(n) is a value indicating the number of times the value of D(n) is changed. Note that the values of the elements C (1), . . . , C (N−1) of the array C at the start of the operation example of FIG. 5 are initialized to 0.

As described above, the signal S_NRF has a maximum value of N−1 and a minimum value of −(N−1) and can take every two values between the maximum value and the minimum value. When N=3, the value of the signal S_NRF is any one of 2, 0, and −2. The value that each element D(n) of the array D can take is 1 or −1.

Further, in the operation example of FIG. 5, the variable s is defined as an intermediate variable, and an array J, an array L, and an array M are defined as intermediate arrays. The array M is an array including integers from 1 to N−1.

The operation example of FIG. 5 will be described based on the above-described assumptions.

First, the N-value signal distributor 31 inputs the signal S_NRF, substitutes the input value of the signal S_NRF into the variable a (Step S1), calculates the difference between the variable a and the variable b into which the previous input value is substituted, and calculates the variable A by dividing the calculated difference by 2 (Step S2).

Next, the N-value signal distributor 31 substitutes the value of the variable a into the variable b (Step S3), and determines the calculated value of A (Step S4).

When the N-value signal distributor 31 determines that A is greater than 0 in Step S4, the N-value signal distributor 31 substitutes −1 into the variable s (Step S5). When the N-value signal distributor 31 determines that A is 0 in Step S4, the N-value signal distributor 31 substitutes 0 into the variable s (Step S6). When the N-value signal distributor 31 determines that A is smaller than 0 in Step S4, the N-value signal distributor 31 substitutes 1 into the variable s (Step S7).

Next, the N-value signal distributor 31 extracts an element number whose value is the value of the variable s from the array B including the previous output values B (1), . . . , B (N−1) as elements, and substitutes the extracted element number into the array J (Step S8).

The N-value signal distributer 31 selects, from the array C, elements having element numbers equal to values of elements of the array J, further selects, from the selected elements of the array C, |Δ| elements in the ascending order of their values from the element having the smallest value, and substitutes the elements numbers of the selected |Δ| elements into the array L (Step S9). The number of times the element number included in the array J is changed is expressed by C (M=J). The array M is an array including integers from 1 to N−1. Among the number of times of the changes C (M=J), |Δ| element numbers with the small number of times of the changes are extracted and substituted into the array L (|Δ| represents an absolute value of Δ).

In the array C, the numbers of times of the changes are set. The N-value signal distributor 31 increments the value of the element of the array C whose element number is included in the array L, and does not change, from the previous value, the value of the element whose the element number is not included in the array L (Step S10). The N-value signal distributor 31 increments the element C (M=L) of the array C whose element number is included in the array L to C (M=L)+1, and holds the element C (M≠L) whose element number is not included in the array L without changing the value from C (M≠L).

The N-value signal distributor 31 substitutes −s, which is a value obtained by multiplying the variable s by −1, into the element of the array D which includes the output values D(1), . . . , D(N−1) as elements including the element number included in the array L, and does not change, from the previous value, the value of the element including the element number not included in the array L (Step S11). The N-value signal distributor 31 substitutes −s, which is a value obtained by multiplying the variable s by −1, into the element D(M=L) of the array D including the element number included in the array L, and holds the element D(M≠L) including the element number not included in the array L without changing the value from D(M≠L).

Lastly, the N-value signal distributor 31 substitutes the elements of the array D having the same element numbers as those of the element numbers of the elements of the element B into the values of the elements of the array B (Step S12), and outputs the elements of the array D as the output values D(1), . . . , D(N−1) (Step S13).

### <Specific Example of Operation of N-Value Signal Distributor>

Next, a specific example of the operation of the N-value signal distributor 31 described with reference to FIG. 5 will be described using specific assumed values.

First, assume that N=3, the input value (value of variable a) input to the N-value signal distributor 31 is 0 (variable a=0), and the previous input value (value of variable b) input to the N-value signal distributor 31 is −2 (variable b=−2). Further assume that the previous output array B of the N-value signal distributor 31 is the array B=[−1, −1], and the array C into which the numbers of times of the changes are set is the array C=[10, 11].

In this case, since Δ=(0+2)/2=1 (Step S2) and N-value signal distributor 31 determines that A is greater that 0 (Step S4), variable s=−1 (Step S5).

Since the two elements of the array B are −1, the element numbers 1 and 2 of the array B are substituted into the array J, and the array J=[1, 2] (Step S8).

Since the array J is the array J=[1, 2], |Δ|=1 element is extracted in an ascending order of the element numbers 1 and 2 of the array C into which the numbers of times of the changes are set. Since the element corresponding to the element number of 1 in the array C is C(1)=10, and the element corresponding to the element number of 2 in the array C is C(2)=11, C(1) with a smaller value is extracted, and the element number 1 of C(1) is substituted into the array L (Step S9).

Since the element number included in the array L is 1, the array D including the output values D(1), . . . , D(N−1) of the N-value signal distributor 31 as elements is D(1)=−s=1, and D(2)=B (2)=−1. Here, a sum of the elements of the array D is 0, which matches the variable a into which the input value of the N-value signal distributor 31 is substituted. That is, the array D that can reproduce the variable a into which the input value of the N-value signal distributor 31 is substituted has a plurality of combinations as long as the variable a is not the maximum value or the minimum value of the signal S_NRF. In this embodiment, the number of times of the changes in the signal is reduced by setting the array D including the current output values as respective elements in such a way that the change from the array B including the previous output values as respective elements is minimized.

Here, a specific example of the signals D(1) and D(2) output from the N-value signal distributor 31 is shown with reference to FIG. 4. In FIG. 4, the second diagram from the bottom is the time chart of D(1) output from the N-value signal distributor 31 when the signal S_NRF is the third from the top, and the bottom diagram is the time chart of D(2) output from the N-value signal distributor 31. The N-value signal distributor 31 divides the signal S_NRF and outputs D(1) and D(2) in such a way that the number of times of the changes in the signals D(1) and D(2) is reduced.

### <Comparison Between Transmitter Using Binary ΔΣ Modulator and Transmitter Using Ternary ΔΣ Modulator>

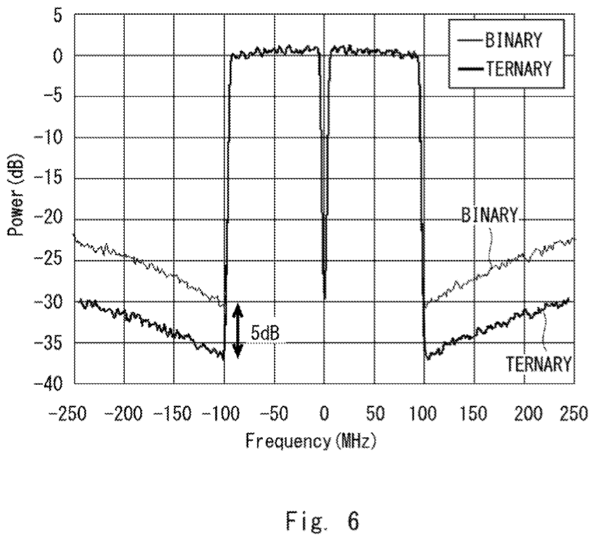

A result of a comparison between the transmitter using a binary ΔΣ modulator and a transmitter using a ternary ΔΣ modulator is described using FIG. 6. FIG. 6 shows a result of the comparison between the transmitter using a binary ΔΣ modulator and a transmitter using a ternary ΔΣ modulator.

More specifically, FIG. 6 shows a result of a comparison between a spectrum when the binary ΔΣ modulator is used and a spectrum when the ternary ΔΣ modulator is used, when the sampling rate in a case where the binary ΔΣ modulator is used is equal to the sampling rate in a case where the ternary ΔΣ modulator is used. In FIG. 6, the spectrum when the binary ΔΣ modulator is used is shown with a thin solid line, while the spectrum when the ternary ΔΣ modulator is used is shown with a thick solid line. As shown in FIG. 6, when the ternary ΔΣ modulator is used, an S/N ratio is improved by 5 dB as compared with when the binary ΔΣ modulator is used.

On the other hand, when the S/N ratio in a case where the binary ΔΣ modulator is used may be the same as the S/N ratio in a case where the ternary ΔΣ modulator is used, the sampling rate can be reduced to about ⅔ by using the ternary ΔΣ modulator, although it may depends on the reference sampling rate.

As described above, the transmitter 100 according to the second example embodiment can transmit a transmission signal that satisfies a higher S/N ratio than the S/N ratio of a transmission signal transmitted by the transmitter according to the related art using the binary ΔΣ modulator.

In the transmitter 100 according to the second example embodiment, the amplification unit 41 is configured by a digital amplifier. When a digital amplifier is used, commonly only binary signals can be amplified, and in order to satisfy a high S/N ratio, it is necessary to sufficiently increase the sampling rate. However, it is difficult to amplify a transmission signal having a high sampling rate with high power efficiency, and the cost of the digital amplifier tends to increase.

The transmitter 100 according to the second example embodiment includes an N-value signal distributor 31. The N-value signal distributor 31 divides the N-value signal into binary signals, and the digital amplifier that constitutes the amplification unit 41 amplifies the binary signals, and the synthesizer 50 combines the signals amplified by the amplification unit 41. In this manner, it is possible to output a transmission signal that satisfies an S/N ratio equivalent to that of an N-value signal by using the transmitter 100 according to the second embodiment.

The digital amplifier loses power mainly in the process in which the output value is changed. However, the N-value signal distributor 31 outputs a binary digital signal in such a way that the change of the output value becomes small, and thus the transmitter 100 can amplify a transmission signal with high power efficiency. Therefore, by using the transmitter 100 according to the second example embodiment, it is possible to achieve a high S/N ratio and high power efficiency at a relatively low sampling rate.

Examples of a technique for obtaining a signal amplified using a plurality of amplifiers are LINC (Linear Amplification with Nonlinear Components) and Outphasing. These techniques are characterized by dividing an amplitude-phase-modulated signal into a plurality of signals each having a constant amplitude, amplifying each of the signals by an amplifier, and then combining them to thereby obtain an amplified amplitude-phase-modulated signal. By using these techniques, each amplifier can be operated in a saturated state, because the amplifier amplifies a signal having a constant amplitude, and thus the signal can be amplified with high power efficiency.

However, when a transmitter is implemented using the above techniques, an apparatus becomes complicated and large, because input signals in a plurality of RF bands are required, and thus there is a concern about an increase in power consumption. More specifically, when a transmitter is implemented using the above techniques, it is necessary to prepare a set of a multi-bit DAC, a quadrature modulator, and a local oscillator outside a DFE, and the number of the sets of the multi-bit DAC, the quadrature modulator, and the local oscillator needs to be the same as the number of RF signals to be generated.

On the other hand, the transmitter 100 according to this embodiment includes a 1-bit DAC inside the DFE, and thus does not require a multi-bit DAC. Furthermore, since the transmitter 100 according to this embodiment outputs an RF band signal directly from the 1-bit DAC, a quadrature modulator and a local oscillator can be built inside the DFE. Thus, with the transmitter 100 according to this embodiment, the configuration of the transmitter can be simplified, the development cost of the transmitter can be reduced, and the power consumption in the transmitter can also be reduced.

Recently, in the field of mobile communication, a wireless apparatus including a plurality of transceivers and supporting a MIMO (Multi-Input Multi-Output) function is becoming common. In the 5th generation mobile communication system, which is expected to be commercialized in the future, it has been discussed to employ Massive-MIMO technology that uses more transceivers. In a radio base station to which the Massive-MIMO technology is applied, power consumption, occupied volume, and cost of a transmitter relative to the entire radio base station tend to increase. For this reason, a transmitter that can amplify a transmission signal with high power efficiency can be designed in a small size and at low cost is required as a transmitter of the radio base station. As described above, with the transmitter 100 according to the second example embodiment, the configuration of the transmitter can be simplified, the development cost of the transmitter can be reduced, and the power consumption of the transmitter can also be reduced. Thus, the transmitter 100 according to the second example embodiment can be used as a transmitter required for the radio base station.

Furthermore, in the transmitter 100 according to the second example embodiment, since the amplification unit 41 is configured by a digital amplifier, it is possible to amplify a signal with higher power efficiency than when an analog amplifier is used.

### Modified Example 1

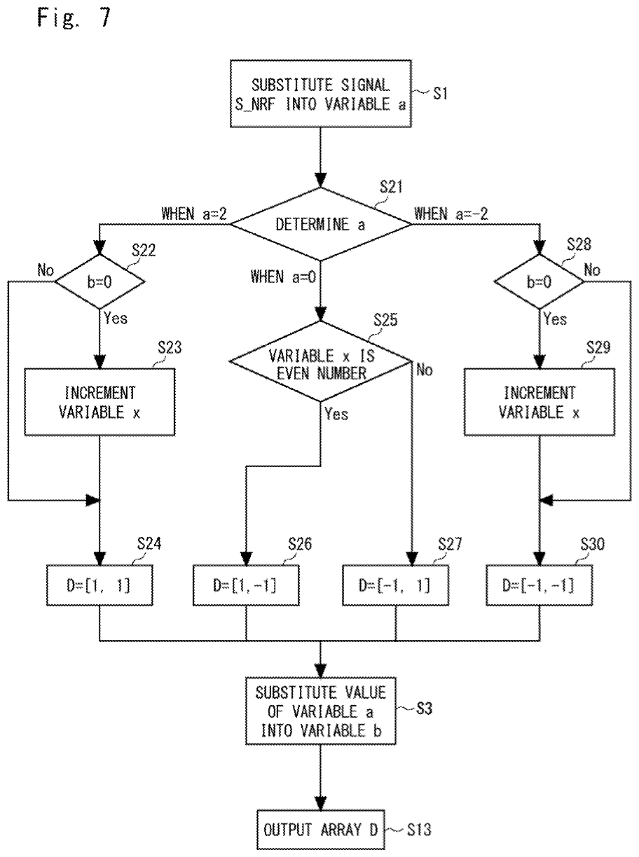

The operation example of the N-value signal distributor 31 described with reference to FIG. 5 may be simplified as shown in FIG. 7 when N=3. FIG. 7 shows an operation example of the N-value signal distributor according to a modified example of the second example embodiment. The same operations of FIG. 7 as those of FIG. 5 are denoted by the same reference numbers as those of FIG. 5.

The N-value signal distributor 31 substitutes the input value of the signal S_NRF into the variable a (Step S1), and determines the value of the variable a (Step S21).

When the variable a is 2, the N-value signal distributor 31 determines whether the variable b into which the previous input value of the signal S_NRF is substituted is 0 (Step S22).

When the variable b is 0 (YES in Step S22), the N-value signal distributor 31 increments the variable x (Step S23), and sets the array D including the output values D(1) and D(2) as elements to create an array D=[1, 1] (Step S24).

On the other hand, when the variable b is not 0 (NO in Step S22), the N-value signal distributor 31 sets an array D including the output values D(1) and D(2) as elements to create an array D=[1, 1] (Step S24).

When the variable a is 0, the N-value signal distributor 31 determines whether the variable x is an even number (Step S25).

When the variable x is an even number (YES in Step S25), the array D is set as the array D=[1, −1] (Step S26).

On the other hand, when the variable x is not an even number (NO in Step S25), the N-value signal distributor 31 sets the array D as the array D=[−1, 1] (Step S27).

When the variable a is −2, the N-value signal distributor 31 determines whether the variable b into which the previous input value of the signal S_NRF is substituted is 0 (Step S28).

When the variable b is 0 (YES in Step S28), the N-value signal distributor 31 increments the variable x (Step S29), and sets the array D as the array D=[−1, 1] (Step S30).

On the other hand, when the variable b is not 0 (NO in Step S28), the N-value signal distributor 31 sets the array D as the array D=[−1, −1] (Step S30).

When Steps S24, S26, S27, and S30 are executed, the N-value signal distributor 31 substitutes the value of the variable a into the variable b (Step S3), determines each element D(1) and D(2) of the array D as the output values, and outputs the D(1) and D(2) (Step S13).

For example, when the value of the signal S_NRF is 2, the N-value signal distributor 31 determines the array D as the array D=[1, 1] and outputs D(1) and D(2). At this time, when the value of the signal S_NRF one sample before is 0, the N-value signal distributor 31 increments the value of the variable x by one.

When the value of the signal S_NRF is −2, the N-value signal distributor 31 determines the array D as the array D=[−1, −1], and outputs D(1) and D(2). At this time, when the value of the signal S_NRF one sample before is 0, the N-value signal distributor 31 increments the value of the variable x by one.

When the value of the signal S_NRF is 0, the N-value signal distributor 31 first determines whether the variable x is an even number or an odd number. When the variable x is an even number, the N-value signal distributor 31 determines the array as the array D=[1, −1], and outputs D(1) and D(2). When the variable x is an odd number, the N-value signal distributor 31 determines that the array D as the array D=[−1, 1], and outputs D(1) and D(2).

### Modified Example 2

Although the transmitter 100 according to the second example embodiment has been described that it performs in-phase combination, it may be configured to perform reverse-phase combination. In this case, the N-value signal distributor 31 changes the array D including the output values of the N-value signal distributor 31 as the respective elements by inverting the sign of the output value 1 or −1 of the element number that is in the reverse phase. For example, when N=3, and the input value of the signal S_NRF is 2, and in the case of in-phase combination, the array D becomes the array D=[1, 1], but in the case of reverse-phase combination, the array becomes the array D=[1, −1]. Configurations according to the modified example 2 other than the above-described point are the same as those of the second example embodiment.

### Modified Example 3

In the second example embodiment, it has been described that the amplification unit 41 is configured by a digital amplifier. However, the amplification unit 41 may be configured by an analog amplifier instead of the digital amplifier. At this time, a filter for removing a main signal out-of-band component may be provided before the amplification unit 41, and after a signal is converted into an analog signal in advance, the analog signal may be amplified by the analog amplifier.

According to the above embodiment of the present disclosure, it is possible to provide a transmitter and a method capable of transmitting a transmission signal that satisfies a high S/N ratio.

The programs can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto-optical disks), Compact Disc Read Only Memory (CD-ROM), CD-R, CD-R/W, and semiconductor memories (such as mask ROM, Programmable ROM (PROM), Erasable PROM (EPROM), flash ROM, Random Access Memory (RAM), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

Note that the present disclosure is not limited to the above-described embodiments, and can be appropriately changed without departing from the spirit of the present disclosure. Further, the present disclosure may be implemented by appropriately combining the respective embodiments.

For example, the whole or part of the embodiments disclosed above can be described as, but not limited to, the following supplementary notes.

### (Supplementary Note 1)

A transmitter comprising:

a first signal generation unit comprising a distributor configured to input a first N (N: an integer greater than or equal to 3) value digital signal generated from a baseband signal, divide the first N-value digital signal into (N−1) binary digital signals, and output the (N−1) binary digital signals; and

a signal amplification unit configured to amplify each of the (N−1) binary digital signals and output a transmission signal obtained by combining the amplified (N−1) signals.

### (Supplementary Note 2)

The transmitter according to Supplementary note 1, wherein the distributor is configured to count the number of times an output value of each of the (N−1) binary digital signals is changed, and determine the output value of each of the (N−1) binary digital signals based on the number of times the output value of each of the (N−1) binary digital signals is changed.

### (Supplementary Note 3)

The transmitter according to Supplementary note 2, wherein the distributer is configured to calculate a difference between a first input value of the first N-value digital signal at a first time and a second input value of the first N-value digital signal at a second time right before the first time, and the distributor is configured to set the output value of the binary digital signal at the first time to be different from the output value at the second time, the number of the binary digital signals corresponding to the difference.

### (Supplementary Note 4)

The transmitter according to Supplementary note 3, wherein the distributor is configured to set the output value of the binary digital signal at the first time to be different from the output value at the second time in an ascending order of the number of times the output value of each of the (N−1) binary digital signals is changed, the number of the binary digital signals corresponding to the difference.

### (Supplementary Note 5)

The transmitter according to Supplementary note 3 or 4, wherein the number of the binary digital signals corresponding to the difference is obtained by dividing the difference by a minimum change amount of an input value of the first N-value digital signal.

### (Supplementary Note 6)

The transmitter according to any one of Supplementary notes 3 to 5, wherein

the distributor is configured to use a value determined based on the difference as the output value of the binary digital signal at the first time, the output value of the binary digital signal at the first time being changed from the output value at the second time.

### (Supplementary Note 7)

The transmitter according to Supplementary note 6, wherein

when the difference is greater than 0, the distributor uses, as a first value, the output value of the binary digital signal at the first time, the output value at the first time being changed from the output value at the second time, and

when the difference is smaller than 0, the distributor uses, as a second value, the output value of the binary digital signal at the first time, the output value at the first time being changed from the output value at the second time.

### (Supplementary Note 8)

The transmitter according to any one of Supplementary notes 1 to 7, wherein the signal amplification unit is configured to amplify each of the (N−1) binary digital signals using (N−1) digital amplifiers.

### (Supplementary Note 9)

The transmitter according to any one of Supplementary notes 1 to 7, wherein the signal amplification unit is configured to amplify each of the (N−1) binary digital signals using (N−1) analog amplifiers.

### (Supplementary Note 10)

The transmitter according to any one of Supplementary notes 1 to 9, wherein

the baseband signal comprises an I channel signal and a Q channel signal orthogonal to the I channel signal, and

the transmitter further comprises a second signal generation unit including a first N-value ΔΣ modulator configured to modulate the I channel signal to a second N-value digital signal and a second N-value ΔΣ modulator configured to modulate the Q channel signal to a third N-value digital signal, and the second signal generation unit is configured to generate the first N-value digital value based on the second N-value digital signal and the third N-value digital signal.

### (Supplementary Note 11)

A method comprising:

dividing a first N (N: an integer greater than or equal to 3) value digital signal generated from a baseband signal into (N−1) binary digital signals and outputting the (N−1) binary digital signals; and

amplifying each of the (N−1) binary digital signals and outputting a transmission signal obtained by combining the amplified (N−1) signals.

The first and second example embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. A transmitter comprising:
a first signal generation unit comprising a distributor configured to input a first N (N: an integer greater than or equal to 3) value digital signal generated from a baseband signal, divide the first N-value digital signal into (N−1) binary digital signals, and output the (N−1) binary digital signals; and
a signal amplification unit configured to amplify each of the (N−1) binary digital signals and output a transmission signal obtained by combining the amplified (N−1) signals.

2. The transmitter according to claim 1, wherein
the distributor is configured to count the number of times an output value of each of the (N−1) binary digital signals is changed, and determine the output value of each of the (N−1) binary digital signals based on the number of times the output value of each of the (N−1) binary digital signals is changed.

3. The transmitter according to claim 2, wherein
the distributer is configured to calculate a difference between a first input value of the first N-value digital signal at a first time and a second input value of the first N-value digital signal at a second time right before the first time, and
the distributor is configured to set the output value of the binary digital signal at the first time to be different from the output value at the second time, the number of the binary digital signals corresponding to the difference.

4. The transmitter according to claim 3, wherein
the distributor is configured to set the output value of the binary digital signal at the first time to be different from the output value at the second time in an ascending order of the number of times the output value of each of the (N−1) binary digital signals is changed, the number of the binary digital signals corresponding to the difference.

5. The transmitter according to claim 3, wherein
the number of the binary digital signals corresponding to the difference is obtained by dividing the difference by a minimum change amount of an input value of the first N-value digital signal.

6. The transmitter according to claim 3, wherein
the distributor is configured to use a value determined based on the difference as the output value of the binary digital signal at the first time, the output value of the binary digital signal at the first time being changed from the output value at the second time.

7. The transmitter according to claim 6, wherein
when the difference is greater than 0, the distributor uses, as a first value, the output value of the binary digital signal at the first time, the output value at the first time being changed from the output value at the second time, and
when the difference is smaller than 0, the distributor uses, as a second value, the output value of the binary digital signal at the first time, the output value at the first time being changed from the output value at the second time.

8. The transmitter according to claim 1, wherein
the signal amplification unit is configured to amplify each of the (N−1) binary digital signals using (N−1) digital amplifiers.

9. The transmitter according to claim 1, wherein
the signal amplification unit is configured to amplify each of the (N−1) binary digital signals using (N−1) analog amplifiers.

10. The transmitter according to claim 1, wherein
the baseband signal comprises an I channel signal and a Q channel signal orthogonal to the I channel signal, and
the transmitter further comprises a second signal generation unit including a first N-value ΔΣ modulator configured to modulate the I channel signal to a second N-value digital signal and a second N-value ΔΣ modulator configured to modulate the Q channel signal to a third N-value digital signal, and the second signal generation unit is configured to generate the first N-value digital value based on the second N-value digital signal and the third N-value digital signal.

11. A method comprising:
dividing a first N (N: an integer greater than or equal to 3) value digital signal generated from a baseband signal into (N−1) binary digital signals and outputting the (N−1) binary digital signals; and
amplifying each of the (N−1) binary digital signals and outputting a transmission signal obtained by combining the amplified (N−1) signals.
